(19) United States
(12) Patent Application Publication
(10) Pub. No.: US 2024/0332443 A1
(43) Pub. Date: Oct. 3, 2024

(54) CHIP FOR VISIBLE LIGHT COMMUNICATION AND PREPARATION METHOD AND APPLICATION THEREOF

(71) Applicant: SOUTH CHINA UNIVERSITY OF TECHNOLOGY, Guangzhou (CN)

(72) Inventors: Guoqiang LI, Guangzhou (CN); Jixing CHAI, Guangzhou (CN); Wenliang WANG, Guangzhou (CN); Hao LI, Guangzhou (CN)

(73) Assignee: SOUTH CHINA UNIVERSITY OF TECHNOLOGY, Guangzhou (CN)

(21) Appl. No.: 18/271,678

(22) PCT Filed: Jan. 25, 2022
(86) PCT No.: PCT/CN2022/073671

§ 371 Date: Jul. 11, 2023

(30) Foreign Application Priority Data
Dec. 14, 2021 (CN) 202111523681.6

(51) Int. Cl. H01L 31/101; H01L 31/0216; H01L 31/0304; H01L 31/18

(52) U.S. Cl. CPC H01L 31/1013; H01L 31/02161; H01L 31/03048; H01L 31/1848; H01L 31/1852; H01L 31/1868

(57) ABSTRACT

A chip for visible-light communication (VLC), a preparation method, and an application of the chip includes a substrate, a buffer layer, an intrinsic GaN layer, a first GaN layer, an i-InₓGa₁₋ₓN functional layer, a second GaN layer, an i-In_{y}Ga_{1-y}N functional layer, a third GaN layer, and a top electrode that are stacked sequentially, where 0≤x<1 and 0≤y≤1. Sidewalls of the i-InₓGa₁₋ₓN functional layer, the second GaN layer, the i-In_{y}Ga_{1-y}N functional layer, and the third GaN layer are each provided with a SiO₂ isolation layer. A bottom electrode is arranged in an upper portion or on a surface of the first GaN layer, and the SiO₂ isolation layer on the sidewall of the i-InₓGa₁₋ₓN functional layer is located between the bottom electrode and the i-InₓGa₁₋ₓN functional layer. Based on the structural design and growth process for the chip for VLC, dual-band detection by a high-bandwidth chip can be implemented.

### CROSS REFERENCES OF THE RELATED APPLICATIONS

This application is the national phase entry of International Application No. PCT/CN2022/073671, filed on Jan. 25, 2022, which is based upon and claims priority to Patent Applications No. CN 202111523681.6, filed on Dec. 14, 2021, the entire contents of which are incorporated herein by reference.

### TECHNICAL FIELD

The present disclosure relates to the technical field of visible-light communication (VLC), particularly to a chip for VLC and a preparation method and an application thereof.

### BACKGROUND

Visible-light communication (VLC) is considered to be one of the important parts of the new generation of mobile communication due to the advantages of broad spectrum, high confidentiality of data transmission, and no electromagnetic radiation to the human body. Meanwhile, modern communication requires extremely high capacity and rate for communication. Therefore, multicolor LED-based VLC systems are proposed to solve this problem. However, this also puts demands on photoelectric detectors, especially on the monolithic integration of multi-band response detectors.

Current photoelectric detectors for VLC research mainly include commercial Si-based detectors and research-specific InGaN-based photoelectric detectors. Since the Si material has a small bandgap (1.1 eV), the Si-based detector is a broad-spectrum response detector. When used in a VLC system, a filter needs to be added to detect a corresponding LED light source, which not only causes the loss of the optical signal but also leads to an increase in the VLC system cost.

The InGaN material with a tunable bandgap (0.7 to 3.4 eV) applies to the operating wavelength of the light source to receive light signals to a maximum extent and effectively reduce noise and system costs, thus becoming the most promising candidate for the VLC photoelectric detector. However, the current research on the InGaN-based photoelectric detector is focused on the single-wavelength PIN-type and metal-semiconductor-metal (MSM)-type detectors. The monolithic integrated chip of the high-performance InGaN-based photoelectric detector with multi-band response needs to be studied. Therefore, designing a multi-band InGaN-based photoelectric detector single chip with a reasonable structure and simple process is of great significance for realizing a high-speed VLC system.

### SUMMARY

The first technical problem is solved by the present disclosure by providing a chip for VLC. Based on the structural design of the chip for VLC, dual-band detection by a high-bandwidth chip can be implemented.

The second technical problem is solved by the present disclosure by providing a method for preparing the chip for VLC.

The third technical problem is solved by the present disclosure by providing an application of the chip for VLC.

To solve the first technical problem, the technical solution adopted by the present disclosure is as follows:

A chip for VLC includes a substrate, a buffer layer, an intrinsic GaN layer, a first GaN layer, an i-InₓGa₁₋ₓN functional layer, a second GaN layer, an i-In_{y}Ga_{1-y}N functional layer, a third GaN layer, and a top electrode that are stacked sequentially, where 0≤x<1, and 0≤y≤1.

Each of the sidewalls of the i-InₓGa₁₋ₓN functional layer, the second GaN layer, the i-In_{y}Ga_{1-y}N functional layer, and the third GaN layer is provided with a SiO₂ isolation layer.

The bottom electrode is arranged in an upper portion of the first GaN layer, and the SiO₂ isolation layer in the sidewall of the i-InₓGa₁₋ₓN functional layer is located between the bottom electrode and the i-InₓGa₁₋ₓN functional layer.

The first GaN layer is an n-GaN or a p-GaN layer.

When the first GaN layer is an n-GaN layer, the second GaN layer is a p-GaN layer, and the third GaN layer is an n-GaN layer.

When the first GaN layer is a p-GaN layer, the second GaN layer is an n-GaN layer, and the third GaN layer is a p-GaN layer.

The photoelectric detector chip may be an n-i-p-i-n structure sharing a p-type material or a p-i-n-i-p structure sharing an n-type material based on two p-i-n structures as required.

According to an implementation of the present disclosure, x>y.

In the i-InₓGa₁₋ₓN functional layer and i-In_{y}Ga_{1-y}N functional layer, a higher In content corresponds to a lower bandgap, where x>y. Therefore, the bandgap of the i-In_{y}Ga_{1-y}N functional layer is higher than that of the i-InₓGa₁₋ₓN functional layer.

According to an implementation of the present disclosure, the i-In_{y}Ga_{1-y}N functional layer made of a high-bandgap material is disposed at the upper portion of the chip, and the i-InₓGa₁₋ₓN functional layer made of a low-bandgap material is disposed at the lower portion of the chip. The combination of the high-bandgap material having a short absorption cutoff wavelength and the low-bandgap material having a long absorption cutoff wavelength maximizes the use of different bands.

According to an implementation of the present disclosure, the i-InₓGa₁₋ₓN functional layer and the i-In_{y}Ga_{1-y}N functional layer each have a 30 to 200 nm thickness.

According to an implementation of the present disclosure, the i-InₓGa₁₋ₓN functional layer is selected from the group consisting of an InₓGa₁₋ₓN film, an InₓGa₁₋ₓN/GaN film, and an InₓGa₁₋ₓN/InGaN film. The i-In_{y}Ga_{1-y}N functional layer is selected from the group consisting of an In_{y}Ga_{1-y}N film, an In_{y}Ga_{1-y}N/GaN film, and an In_{y}Ga_{1-y}N/InGaN film.

Preferably, the InₓGa₁₋ₓN/GaN film is an InₓGa₁₋ₓN/GaN quantum well; the InₓGa₁₋ₓN/InGaN film is an InₓGa₁₋ₓN/InGaN quantum well; the In_{y}Ga_{1-y}N/GaN film is an In_{y}Ga_{1-y}N/GaN quantum well; the In_{y}Ga_{1-y}N/InGaN film is an In_{y}Ga_{1-y}N/InGaN quantum well.

According to an implementation of the present disclosure, the chip for VLC is obtained through monolithic integration.

The photoelectric detector chip loads voltages in different directions, thus achieving photoelectric detection in different bands.

Specifically, under a forward bias voltage of 1.5 V, an operating region of the device is the first GaN layer/i-InₓGa₁₋ₓN functional layer/the second GaN layer. Under a reverse bias voltage of −1.3 V, the operating region of the device is the second GaN layer/the i-In_{y}Ga_{1-y}N functional layer/the third GaN layer.

The chip for VLC has a transverse structure, which increases the integrability of the chip for VLC. On this basis, the chip for VLC can be integrated with a light-emitting diode (LED) and a high electron mobility transistor (HEMT) monolithically; it is also possible to prepare a duplex device through a quantum well structure to realize on-chip light conduction and other functions. In addition, under high-power transmission conditions, it is easier to prepare detector arrays based on using the chip.

A detector prepared by using the chip for VLC can realize an on-chip optical interconnect structure.

To solve the second technical problem, the technical solution adopted by the present disclosure is as follows:

A method for preparing the chip for VLC includes the following steps:
sequentially growing a buffer layer, an intrinsic GaN layer, a first GaN layer, an i-InₓGa₁₋ₓN functional layer, a second GaN layer, an i-In_{y}Ga_{i-y}N functional layer, and a third GaN layer on a substrate;
etching the i-InₓGa₁₋ₓN functional layer, the second GaN layer, the i-In_{y}Ga_{1-y}N functional layer, and the third GaN layer at one side;
depositing a SiO₂ isolation layer in an etched region; and
arranging a bottom electrode in an upper portion of the first GaN layer, where the bottom electrode is spaced apart from the i-InₓGa₁₋ₓN functional layer in a lateral direction; and
arranging a top electrode on the surface of the third GaN layer to obtain the photoelectric detector chip.

According to an implementation of the present disclosure, the substrate is at least one of a silicon substrate, a sapphire substrate, or a silicon carbide substrate and has a 300 to 450 μm thickness.

According to an implementation of the present disclosure, the buffer layer includes an AlN buffer layer and an AlGaN buffer layer stacked together.

According to an implementation of the present disclosure, the AlN buffer layer has a thickness of 50 to 150 nm, and the AlGaN buffer layer has a thickness of 250 to 400 nm.

According to an implementation of the present disclosure, the intrinsic GaN layer has a thickness of 1 to 3 μm.

According to an implementation of the present disclosure, a method for the sequential growth on the substrate includes at least one of the methods of metal-organic chemical vapor deposition (MOCVD), pulsed laser deposition (PLD), and molecular beam epitaxy (MBE).

According to an implementation of the present disclosure, raw materials for growth in the MOCVD include trimethyl gallium (Ga(CH₃)₃, TMGa), trimethyl indium (In(CH₃)₃, TMIn), and trimethyl aluminum (Al(CH₃)₃, TMAI).

According to an implementation of the present disclosure, the grown first GaN layer has a thickness of 1 to 3 μm, the i-InₓGa₁₋ₓN functional layer has a thickness of 80 to 150 nm, the second GaN layer has a thickness of 100 to 150 nm, the i-In_{y}Ga_{1-y}N functional layer has a thickness of 80 to 150 nm, and the third GaN layer has a thickness of 300 to 500 nm.

The dual-band structure is directly grown epitaxially on the substrate without a second growth process. This reduces the process costs required for constructing a multi-band complex structure and simplifies the process steps. In addition, the monolithically integrated chip can solve the problem that the high parasitic capacitance of the common hybrid integrated chip limits the detector bandwidth. The dual-band device can meet the demand of a dual-color LED-based VLC system for photoelectric detector monolithically integrated chips that respond in different bands.

According to an implementation of the present disclosure, during the etching of the i-InₓGa₁₋ₓN functional layer, the second GaN layer, the i-In_{y}Ga_{1-y}N functional layer, and the third GaN layer at one side, the etching reaches into the first GaN layer.

According to an implementation of the present disclosure, the etching includes at least one of the steps of photoresist spin-coating, exposure and development, and inductively coupled plasma dry etching.

According to an implementation of the present disclosure, the SiO₂ isolation layer has a thickness of 200 to 300 nm.

According to an implementation of the present disclosure, sidewalls are passivated by depositing SiO₂ using plasma-enhanced chemical vapor deposition (PECVD) to prepare the SiO₂ isolation layer, where a plasma power is 30 to 50 W and a deposition temperature is 90 to 110° C.

According to an implementation of the present disclosure, the top electrode and the bottom electrode are made from the same materials, for example, Ti/Al/Ni/Au in sequence;
the bottom electrode and the top electrode each have a thickness of 215 to 360 nm.

Deposition of the Ti/Al/Ni/Au electrode on the photoelectric detector chip can form an ohmic contact mechanism. As a cover layer of Ti/Al, Ni/Au can prevent mutual diffusion of Ti, Al, and Au and acts as an antioxidant for the contact layer.

According to an implementation of the present disclosure, the bottom electrode and the top electrode are prepared by using an electron beam evaporation system.

According to an implementation of the present disclosure, the method further includes a step of annealing the bottom electrode and the top electrode at an annealing temperature of 700 to 900° C.

Another aspect of the present disclosure further relates to the application of the chip for VLC in a photoelectric detector.

Any of the technical solutions can achieve at least one of the following beneficial effects:
1. The dual-band structure is directly grown epitaxially on the substrate without a second growth process. This reduces the process costs required for constructing a multi-band complex structure and simplifies the process steps.
2. The photoelectric detector chip loads voltages in different directions, thus achieving photoelectric detection in different bands.
3. In the chip for VLC, the i-In_{y}Ga_{1-y}N functional layer made of a high-bandgap material is disposed at an upper portion of the chip, and the i-InₓGa₁₋ₓN functional layer made of a low-bandgap material is disposed at a lower portion of the chip. The combination of the high-bandgap material having a short absorption cutoff wavelength and the low-bandgap material having a long absorption cutoff wavelength maximizes the use of different bands.

### BRIEF DESCRIPTION OF THE DRAWINGS

The accompanying drawings which constitute a part of the description of the present disclosure are intended to provide a further understanding of the present disclosure. The exemplary examples of the present disclosure and descriptions thereof are intended to explain the present disclosure and do not constitute an inappropriate limitation to the present disclosure.

FIG. 1 is a schematic diagram of an epitaxial structure of a chip for VLC according to Embodiment 1.

FIG. 2 is a sectional view of a device structure of a chip for VLC according to Embodiment 1.

FIG. 3 is a sectional view of a device structure of a chip for VLC according to Embodiment 2.

FIG. 4 is a sectional view of a device structure of a chip for VLC according to Embodiment 3.

FIG. 5 is a sectional view of a device structure of a chip for VLC according to Embodiment 4.

FIG. 6 shows a dual-band response curve of a chip for VLC according to Embodiment 1.

FIG. 7 shows a dual-band bandwidth curve of a chip for VLC according to Embodiment 1.

### DETAILED DESCRIPTION OF THE EMBODIMENTS

The embodiments of the present disclosure are described below in detail. Examples of the embodiments are shown in the drawings. The same or similar numerals represent the same or similar elements or elements having the same or similar functions throughout the specification.

The embodiments described below by referring to the drawings are exemplary. They are only used to explain the present disclosure and should not be construed as a limitation of the present disclosure.

The “first”, “second”, “third” and the like used in the description of the present disclosure are merely intended to distinguish technical features, rather than to indicate or imply relative importance or implicitly indicate a number of the indicated technical features or implicitly indicate a sequence relationship of the indicated technical features.

It should be understood that, in the description of the present disclosure, the orientation or position relationships indicated by terms such as “upper”, “lower”, “front”, “rear”, “left” and “right” are shown in the drawings. These terms are merely intended to facilitate and simplify the description of the present disclosure, rather than to indicate or imply that the mentioned apparatus or components must have a specific orientation or must be constructed and operated in a specific orientation. Therefore, these terms should not be understood as a limitation of the present disclosure.

In the description of the present disclosure, unless otherwise explicitly defined, the words such as “arrange”, “install” and “connect” should be understood in a broad sense, and those skilled in the technical field can reasonably determine the specific meanings of the above words in the present disclosure in combination with specific contents of the technical solutions.

### Embodiment 1

In an i-InₓGa₁₋ₓN functional layer where x=0.4, and the bandgap width is 1.97 eV.

In an i-In_{y}Ga_{1-y}N functional layer where y=0.15, and the bandgap width is 2.81 eV.

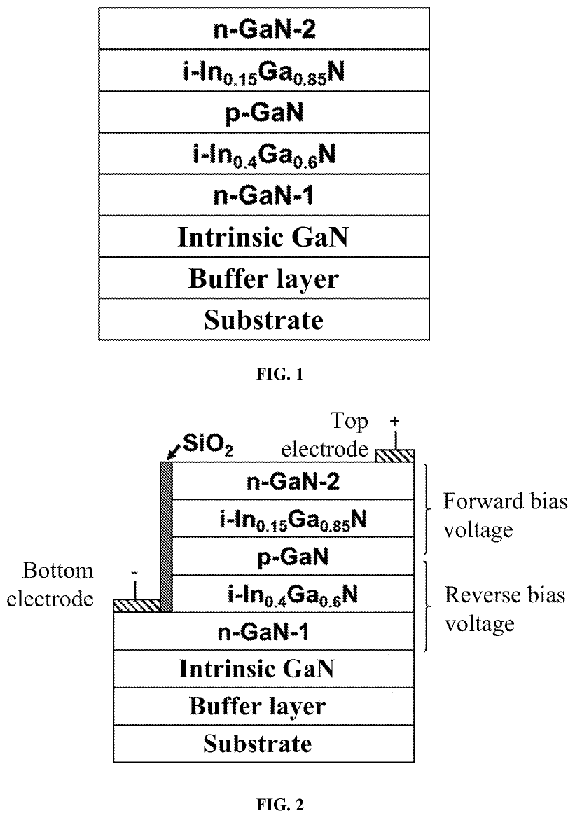

This embodiment provides an epitaxial structure of a chip for VLC, including a substrate, a buffer layer, an intrinsic GaN layer, an n-GaN-1 layer, an i-In_{0.4}Ga_{0.6}N functional layer, a p-GaN layer, an i-In_{0.15}Ga_{0.75}N functional layer, and an n-GaN-2 layer in sequence from bottom to top, as shown in FIG. 1. A growth process is as follows:
(1) On the substrate with a thickness of 300 μm, an MOCVD method is adopted for growth with raw materials of trimethyl gallium (Ga(CH₃)₃, TMGa), trimethyl indium (In(CH₃)₃, TMIn), and trimethyl aluminum (Al(CH₃)₃, TMAI). AlN with a thickness of 50 nm, an AlGaN layer with a thickness of 250 nm, a GaN layer with a thickness of 1 μm, an n-GaN-1 layer with a thickness of 1 μm, an i-In_{0.4}Ga_{0.6}N functional layer with a thickness of 80 nm, a p-GaN layer with a thickness of 100 nm, an i-In_{0.15}Ga_{0.75}N functional layer with a thickness of 80 nm, and n-GaN-2 with a thickness of 300 nm are grown sequentially.

This embodiment further provides a sectional view of a device structure of a chip for VLC, including a substrate, a buffer layer, an intrinsic GaN layer, an n-GaN-1 layer, an i-In_{0.4}Ga_{0.6}N functional layer, a p-GaN layer, an i-In_{0.15}Ga_{0.75}N functional layer, an n-GaN-2 layer, a SiO₂ isolation layer, and an electrode in sequence from bottom to top, as shown in FIG. 2. A specific preparation process is as follows:
(1) Photoresist spin-coating, exposure and development, and inductively coupled plasma (ICP) dry etching are performed on the surface of the n-GaN-2 layer until the n-GaN-1 layer is reached.
(2) Photoresist spin-coating, and exposure and development are performed again on the surface of the n-GaN-2 layer, and then SiO₂ is deposited by using PECVD to passivate the sidewall, where a SiO₂ passivation layer has a thickness of 200 nm.
(3) Photoresist spin-coating, and exposure and development are performed on the surface of the n-GaN-2 layer again, and a metal electrode is prepared by using an electron beam evaporation system, where the electrode is made of Ti, Al, Ni, and Au in sequence with thicknesses of 5 nm, 90 nm, 60 nm, and 60 nm respectively. The prepared electrode is annealed by using a rapid annealing furnace at an annealing temperature of 800° C. for 30s to obtain the chip for VLC.

### Embodiment 2

In an i-InₓGa₁₋ₓN functional layer where x=0.15, and the bandgap width is 2.81 eV.

In an i-In_{y}Ga_{1-y}N functional layer where y=0, and the bandgap width is 3.4 eV.

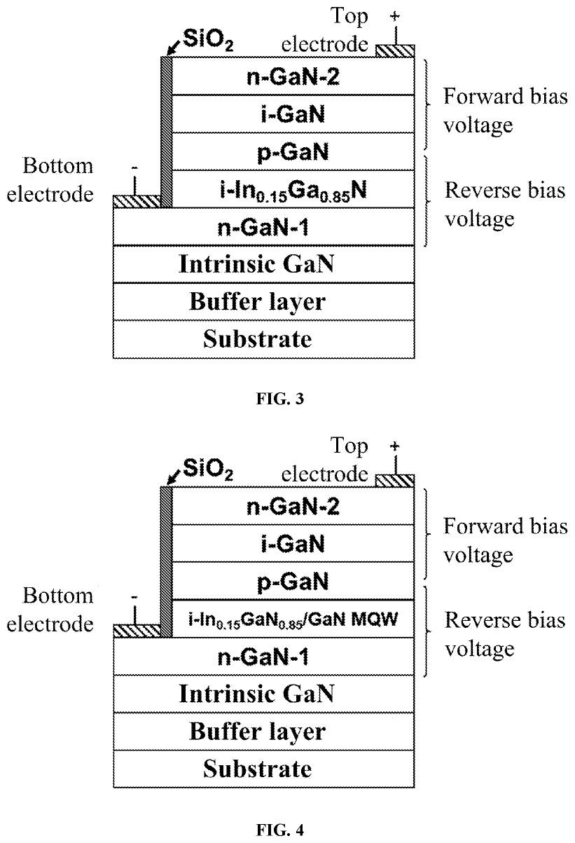

This embodiment provides an epitaxial structure of a chip for VLC, including a substrate, a buffer layer, an intrinsic GaN layer, an n-GaN-1 layer, an i-In_{0.15}Ga_{0.75}N functional layer, a p-GaN layer, an i-GaN functional layer, and an n-GaN-2 layer in sequence from bottom to top, as shown in FIG. 3. A growth process is as follows:
(1) On the substrate with a thickness of 400 μm, an MBE method is adopted for growth with raw materials of high-purity indium (In, 99.99999%), high-purity gallium (Ga, 99.99999%), and high-purity aluminum (Al, 99.99999%). AlN with a thickness of 100 nm, an AlGaN layer with a thickness of 300 nm, a GaN layer with a thickness of 2 μm, an n-GaN-1 layer with a thickness of 2 μm, an i-In_{0.15}Ga_{0.75}N functional layer with a thickness of 100 nm, a p-GaN layer with a thickness of 130 nm, an i-GaN functional layer with a thickness of 400 nm, and n-GaN-2 with a thickness of 300 nm are grown sequentially.

This embodiment provides a sectional view of a device structure of a chip for VLC, including a substrate, a buffer layer, an intrinsic GaN layer, an n-GaN-1 layer, an i-In_{0.15}Ga_{0.75}N functional layer, a p-GaN layer, an i-GaN functional layer, an n-GaN-2 layer, a SiO₂ isolation layer, and an electrode in sequence from bottom to top. A specific preparation process is as follows:
(1) Photoresist spin-coating, exposure and development, and ICP dry etching are performed on the surface of the n-GaN-2 layer until the n-GaN-1 layer is reached.
(2) Photoresist spin-coating, and exposure and development are performed again on the surface of the n-GaN-2 layer, and then SiO₂ is deposited by using PECVD to passivate the sidewall, where a SiO₂ passivation layer has a thickness of 230 nm.
(3) Photoresist spin-coating, and exposure and development are performed on the surface of the n-GaN-2 layer again, and a metal electrode is prepared by using an electron beam evaporation system, where the electrode is made of Ti, Al, Ni, and Au in sequence with thicknesses of 5 nm, 120 nm, 80 nm, and 80 nm respectively. The prepared electrode is annealed by using a rapid annealing furnace at an annealing temperature of 830° C. for 40s to obtain the chip for VLC.

### Embodiment 3

In an i-InₓGa₁₋ₓN functional layer where x=0.15, and the bandgap width is 2.81 eV.

In an i-In_{y}Ga_{1-y}N functional layer where y=0, and the bandgap width is 3.4 eV.

This embodiment provides an epitaxial structure of a chip for VLC, including a substrate, a buffer layer, an intrinsic GaN layer, an n-GaN-1 layer, an i-In_{0.15}Ga_{0.75}N/GaN quantum well functional layer, a p-GaN layer, an i-GaN functional layer, and an n-GaN-2 layer in sequence from bottom to top, as shown in FIG. 4. A growth process is as follows:
(1) On the substrate with a thickness of 450 μm, a PLD method is adopted for growth with raw materials of high-purity indium (In, 99.99999%), high-purity gallium (Ga, 99.99999%), and high-purity aluminum (Al, 99.99999%). AlN with a thickness of 150 nm, an AlGaN layer with a thickness of 400 nm, a GaN layer with a thickness of 3 μm, an n-GaN-1 layer with a thickness of 3 μm, an i-InN functional layer with a thickness of 150 nm, a p-GaN layer with a thickness of 150 nm, an i-In_{0.15}Ga_{0.75}N/GaN quantum well functional layer with a thickness of 150 nm, and n-GaN-2 with a thickness of 500 nm are grown sequentially.

This embodiment further provides a sectional view of a device structure of a chip for VLC, including a substrate, a buffer layer, an intrinsic GaN layer, an n-GaN-1 layer, an i-InN functional layer, a p-GaN layer, an i-In_{0.15}Ga_{0.75}N/GaN quantum well functional layer, an n-GaN-2 layer, a SiO₂ isolation layer, and an electrode in sequence from bottom to top. A specific preparation process is as follows:
(1) Photoresist spin-coating, exposure and development, and ICP dry etching are performed on the surface of the n-GaN-2 layer until reaching 10 nm deep within the n-GaN-1 layer.
(2) Photoresist spin-coating and exposure and development are performed again on the surface of the n-GaN-2 layer, and then SiO₂ is deposited by using PECVD to passivate the sidewall, where a SiO₂ passivation layer has a thickness of 250 nm.
(3) Photoresist spin-coating, and exposure and development are performed on the surface of the n-GaN-2 layer again, and an electrode is prepared by using an electron beam evaporation system, where the electrode is made of Ti, Al, Ni, and Au in sequence with thicknesses of 10 nm, 150 nm, 100 nm, and 100 nm respectively. The prepared electrode is annealed by using a rapid annealing furnace at an annealing temperature of 850° C. for 50 s to obtain the chip for VLC.

### Embodiment 4

In an i-InₓGa₁₋ₓN functional layer where x=0.4, and the bandgap width is 1.97 eV. In an i-In_{y}Ga_{1-y}N functional layer where y=0.15, and the bandgap is 2.81 eV.

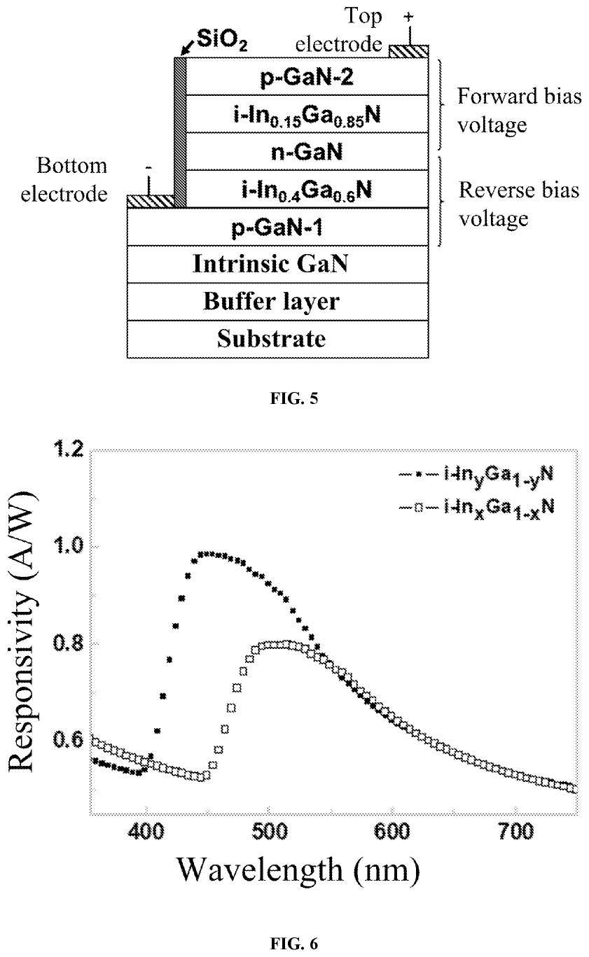

This embodiment provides an epitaxial structure of a chip for VLC, including a substrate, a buffer layer, an intrinsic GaN layer, a p-GaN-1 layer, an i-In_{0.4}Ga_{0.6}N functional layer, an n-GaN layer, an i-In_{0.15}Ga_{0.75}N layer, and a p-GaN-2 layer in sequence from bottom to top, as shown in FIG. 5. A growth process is as follows:
(1) On the substrate with a thickness of 300 μm, an MOCVD method is adopted for growth with raw materials of trimethyl gallium (Ga(CH₃)₃, TMGa), trimethyl indium (In(CH₃)₃, TMIn), and trimethyl aluminum (Al(CH₃)₃, TMAI). AlN with a thickness of 50 nm, an AlGaN layer with a thickness of 250 nm, a GaN layer with a thickness of 1 μm, a p-GaN-1 layer with a thickness of 1 μm, an i-In_{0.4}Ga_{0.6}N functional layer with a thickness of 80 nm, an n-GaN layer with a thickness of 100 nm, an i-In_{0.15}Ga_{0.75}N functional layer with a thickness of 80 nm, and p-GaN-2 with a thickness of 300 nm are grown sequentially.

This embodiment provides a sectional view of a device structure of a chip for VLC, including a substrate, a buffer layer, an intrinsic GaN layer, a p-GaN-1 layer, an i-In_{0.4}Ga_{0.6}N functional layer, an n-GaN layer, an i-In_{0.15}Ga_{0.75}N functional layer, a p-GaN-2 layer, a SiO₂ isolation layer, and an electrode in sequence from bottom to top, as shown in FIG. 3. A specific preparation process is as follows:
(1) Photoresist spin-coating, exposure and development, and ICP dry etching are performed on the surface of the p-GaN-2 layer until the p-GaN-1 layer is reached.
(2) Photoresist spin-coating and exposure and development are performed again on the surface of the p-GaN-2 layer, and SiO₂ is then deposited by using PECVD to passivate the sidewall, where a SiO₂ passivation layer has a thickness of 200 nm.
(3) Photoresist spin-coating and exposure and development are performed on the surface of the p-GaN-2 layer again. A metal electrode is prepared by using an electron beam evaporation system, where the electrode is made of Ti, Al, Ni, and Au in sequence with thicknesses of 5 nm, 90 nm, 60 nm, and 60 nm respectively. The prepared electrode is annealed by using a rapid annealing furnace at an annealing temperature of 800° C. for 30 s to obtain the chip for VLC.

### Performance Testing:

FIG. 6 shows a dual-band response curve of a chip for VLC according to Embodiment 1. Under a forward bias voltage of 1.5 V, the operating region of the device is n-GaN-1/i-In_{0.4}Ga_{0.6}N/p-GaN, and the responsiveness of the device is 0.81 A/W.

Under a reverse bias voltage of −1.3 V, the operating region of the device is n-GaN-2/i-In_{0.15}Ga_{0.75}N/p-GaN, and the responsiveness of the device is 0.98 A/W.

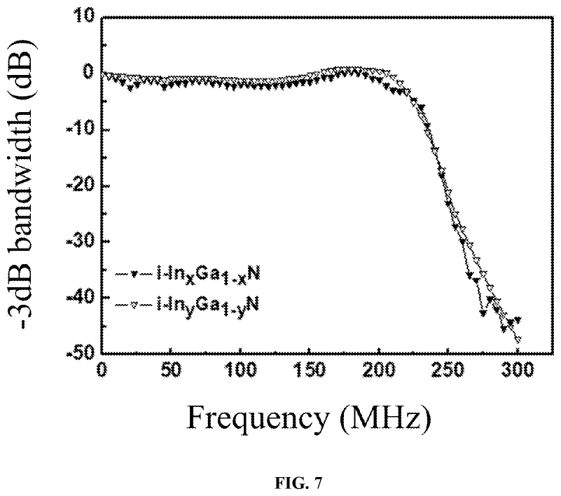

FIG. 7 shows a dual-band bandwidth curve of a chip for VLC according to Embodiment 1. Under a forward bias voltage of 1.5 V, the operating region of the device is n-GaN-1/i-In_{0.4}Ga_{0.6}N/p-GaN, and the −3 dB bandwidth of the device is 210 MHz.

Under a reverse bias voltage of −1.3 V, the operating region of the device is n-GaN-2/i-In_{0.15}Ga_{0.75}N/p-GaN, and the −3 dB bandwidth of the device is 220 MHz.

The foregoing are merely embodiments of the present disclosure and do not constitute a limitation on the scope of the present disclosure. Any equivalent change made by using the description and the accompanying drawings of the present disclosure, or the direct or indirect application thereof in related technical fields, shall still fall in the protection scope of the patent of the present disclosure.

What is claimed is:

1. A chip for visible-light communication (VLC), comprising:
a substrate, a buffer layer, an intrinsic GaN layer, a first GaN layer, an i-InₓGa₁₋ₓN functional layer, a second GaN layer, an i-In_{y}Ga_{1-y}N functional layer, a third GaN layer, and a top electrode that are stacked sequentially, wherein 0≤x<1, and 0≤y≤1;
sidewalls of the i-InₓGa₁₋ₓN functional layer, the second GaN layer, the i-In_{y}Ga_{1-y}N functional layer, and the third GaN layer are each provided with a SiO₂ isolation layer;
a bottom electrode is arranged in an upper portion of the first GaN layer, and the SiO₂ isolation layer on the sidewall of the i-InₓGa₁₋ₓN functional layer is located between the bottom electrode and the i-InₓGa₁₋ₓN functional layer;
the first GaN layer is an n-GaN or a p-GaN layer:
when the first GaN layer is an n-GaN layer, the second GaN layer is a p-GaN layer, and the third GaN layer is an n-GaN layer; and
when the first GaN layer is a p-GaN layer, the second GaN layer is an n-GaN layer, and the third GaN layer is a p-GaN layer.

2. The chip for VLC according to claim 1, wherein x>y.

3. The chip for VLC according to claim 1, wherein the i-InₓGa₁₋ₓN functional layer and the i-In_{y}Ga_{1-y}N functional layer each have a thickness of 30 to 200 nm.

4. The chip for VLC according to claim 3, wherein the i-InₓGa₁₋ₓN functional layer is selected from the group consisting of an InₓGa₁₋ₓN film, an InₓGa₁₋ₓN/GaN film, and an InₓGa₁₋ₓN/InGaN film; and the i-In_{y}Ga_{1-y}N functional layer is selected from the group consisting of an In_{y}Ga_{1-y}N film, an In_{y}Ga_{1-y}N/GaN film, and an In_{y}Ga_{1-y}N/InGaN film.

5. A method for preparing the chip for VLC according to claim 1, comprising the following steps:
sequentially growing a buffer layer, an intrinsic GaN layer, a first GaN layer, an i-InₓGa₁₋ₓN functional layer, a second GaN layer, an i-In_{y}Ga_{1-y}N functional layer, and a third GaN layer on a substrate;
etching the i-InₓGa₁₋ₓN functional layer, the second GaN layer, the i-In_{y}Ga_{1-y}N functional layer, and the third GaN layer at one side of the chip to form an etched region;
depositing a SiO₂ isolation layer in the etched region; and
arranging a bottom electrode in an upper portion or on a surface of the first GaN layer, wherein the bottom electrode is spaced apart from the i-InₓGa₁₋ₓN functional layer; and arranging a top electrode on a surface of the third GaN layer to obtain the photoelectric detector chip.

6. The method according to claim 5, wherein the etching comprises at least one of photoresist spin-coating, exposure and development, and inductively coupled plasma dry etching.

7. The method according to claim 5, wherein the SiO₂ isolation layer has a thickness of 200 to 300 nm.

8. The method according to claim 5, wherein the bottom electrode and the top electrode are made from same materials comprising Ti/Al/Ni/Au in sequence; and
the bottom electrode and the top electrode each have a thickness of 215 to 360 nm.

9. The method according to claim 8, further comprising a step of annealing the bottom electrode and the top electrode at an annealing temperature of 700 to 900° C.

10. An application of the chip for VLC according to claim 1 in a photoelectric detector.

11. The method for preparing the chip for VLC according to claim 5, wherein x>y.

12. The method for preparing the chip for VLC according to claim 5, wherein the i-InₓGa₁₋ₓN functional layer and the i-In_{y}Ga_{1-y}N functional layer each have a thickness of 30 to 200 nm.

13. The method for preparing the chip for VLC according to claim 12, wherein the i-InₓGa₁₋ₓN functional layer is selected from the group consisting of an InₓGa₁₋ₓN film, an InₓGa₁₋ₓN/GaN film, and an InₓGa₁₋ₓN/InGaN film; and the i-In_{y}Ga_{1-y}N functional layer is selected from the group consisting of an In_{y}Ga_{1-y}N film, an In_{y}Ga_{1-y}N/GaN film, and an In_{y}Ga_{1-y}N/InGaN film.

14. An application of the chip for VLC according to claim 2 in a photoelectric detector.

15. An application of the chip for VLC according to claim 3 in a photoelectric detector.

16. An application of the chip for VLC according to claim 4 in a photoelectric detector.
